(19) United States
(12) Patent Application Publication
(10) Pub. No.: US 2025/0241135 A1
(43) Pub. Date: Jul. 24, 2025

(54) DISPLAY DEVICE AND METHOD OF MANUFACTURING THE DISPLAY DEVICE

(71) Applicant: Samsung Display Co., Ltd., Yongin-si (KR)

(72) Inventors: Arong Kim, Yongin-si (KR); Youngmin Moon, Yongin-si (KR); Heemin Park, Yongin-si (KR); Hyuneok Shin, Yongin-si (KR); Samin Lee, Yongin-si (KR); Sungsoon Im, Yongin-si (KR)

(73) Assignee: Samsung Display Co., Ltd., Yongin-si (KR)

(21) Appl. No.: 18/829,899

(22) Filed: Sep. 10, 2024

(30) Foreign Application Priority Data
Jan. 18, 2024 (KR) 10-2024-0008290

(51) Int. Cl. H10K 59/122; H10K 59/12; H10K 59/80

(52) U.S. Cl. CPC H10K 59/122; H10K 59/1201; H10K 59/8794

(57) ABSTRACT

A display device includes a circuit element layer disposed on a substrate and including a pixel circuit, a first pixel electrode disposed on the circuit element layer, a bank layer disposed on the circuit element layer and including a first-1 opening that exposes a part of the first pixel electrode, a heating electrode disposed on the bank layer and including a second-1 opening that overlaps the first-1 opening, a first emission layer disposed on the first pixel electrode, accommodated in the first-1 opening, and spaced apart from the heating electrode, and a first common electrode disposed on the first emission layer, accommodated in the second-1 opening, and contacting the heating electrode.

### CROSS-REFERENCE TO RELATED APPLICATION

This application claims priority to and benefits of Korean Patent Application No. 10-2024-0008290 under 35 U.S.C. § 119, filed on Jan. 18, 2024, in the Korean Intellectual Property Office (KIPO), the disclosure of which is incorporated herein by reference in its entirety.

### BACKGROUND

### 1. Technical Field

One or more embodiments relate to a device and a method, and more particularly, to a display device and a method of manufacturing the display device.

### 2. Description of the Related Art

Mobile electronic devices have been widely used. In addition to compact electronic devices such as mobile phones, tablet personal computers (PCs) have recently been widely used as mobile electronic devices.

In order to support various functions, these mobile electronic devices include display devices to provide visual information such as images or videos to users. Recently, as other components for driving display devices have become smaller, the proportion of display devices in electronic devices has gradually increased, and structures that may be bent to a certain angle from a flat state have been developed.

### SUMMARY

One or more embodiments include a method of manufacturing a display device, the method being capable of reducing a phenomenon in which an emission layer is damaged during a manufacturing process for a display device and minimizing the number of deposition masks required.

However, these objectives are only examples, and the technical objectives of one or more embodiments are not limited thereto.

Additional aspects will be set forth in part in the description which follows and, in part, will be apparent from the description, or may be learned by practice of the presented embodiments of the disclosure.

According to one or more embodiments, a display device includes a circuit element layer disposed on a substrate and including a pixel circuit, a first pixel electrode disposed on the circuit element layer, a bank layer disposed on the circuit element layer and including a first-1 opening that exposes a part of the first pixel electrode, a heating electrode disposed on the bank layer and including a second-1 opening that overlaps the first-1 opening, a first emission layer disposed on the first pixel electrode, accommodated in the first-1 opening, and spaced apart from the heating electrode, and a first common electrode disposed on the first emission layer, accommodated in the second-1 opening, and contacting the heating electrode.

An end of the first emission layer may be convex.

The first common electrode may cover the first emission layer.

The display device may further include a barrier layer having an insulating material and disposed on the heating electrode.

The display device may further include a first-1 functional layer disposed between the first pixel electrode and the first emission layer and spaced apart from the heating electrode.

The display device may further include a first-2 functional layer disposed between the first emission layer and the first common electrode and contacting the heating electrode.

The display device may further include a second pixel electrode disposed on the circuit element layer and spaced apart from the first pixel electrode, a second emission layer disposed on the second pixel electrode and spaced apart from the heating electrode, and a second common electrode disposed on the second emission layer and contacting the heating electrode.

The first emission layer and the second emission layer may emit light of different colors.

The first common electrode and the second common electrode may be spaced apart from each other.

According to one or more embodiments, a method of manufacturing a display device includes disposing a circuit element layer on a substrate, disposing a first pixel electrode, a second pixel electrode, and a third pixel electrode on the circuit element layer, disposing a bank layer on the circuit element layer, the bank layer including a first-1 opening that exposes a part of the first pixel electrode, a first-2 opening that exposes a part of the second pixel electrode, and a first-3 opening that exposes a part of the third pixel electrode, disposing a heating electrode on the bank layer, disposing a first emission layer on the first pixel electrode, the second pixel electrode, and the third pixel electrode, and performing a first Joule heating on the heating electrode.

In the disposing of the first emission layer, the first emission layer may contact the heating electrode.

In the performing of the first Joule heating on the heating electrode, the first emission layer may be spaced apart from the heating electrode.

In the performing of the first Joule heating on the heating electrode, an end of the first emission layer may be convex.

The method may further include disposing a first sacrificial layer on the first emission layer arranged in the first-1 opening, disposing a first photoresist layer on the first sacrificial layer, removing the first emission layer disposed on the second pixel electrode and the third pixel electrode, and removing the first photoresist layer.

The method may further include disposing a second emission layer on the first sacrificial layer, the second pixel electrode, and the third pixel electrode, performing a second Joule heating on the heating electrode, disposing a second sacrificial layer on the second emission layer arranged in the first-2 opening, disposing a second photoresist layer on the second sacrificial layer, removing the second emission layer disposed on the first pixel electrode and the third pixel electrode, and removing the second photoresist layer.

The first emission layer and the second emission layer may emit light of different colors.

The method may further include disposing a third emission layer on the first sacrificial layer, the second sacrificial layer, and the third pixel electrode, performing a third Joule heating on the heating electrode, disposing a third sacrificial layer on the third emission layer arranged in the first-3 opening, disposing a third photoresist layer on the third sacrificial layer, removing the third emission layer disposed on the first pixel electrode and the second pixel electrode, and removing the third photoresist layer.

The method may further include removing the first sacrificial layer, the second sacrificial layer, and the third sacrificial layer.

The method may further include disposing a first common electrode on the first emission layer to contact the heating electrode, disposing a second common electrode on the second emission layer to contact the heating electrode, and disposing a third common electrode on the third emission layer to contact the heating electrode.

The disposing of the first common electrode, the disposing of the second common electrode, and the disposing of the third common electrode may be simultaneously performed.

Other aspects, features, and advantages in addition to those described above would become apparent from the following drawings, claims, and detailed description of one or more embodiments.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display device according to an embodiment;

FIGS. 2 and 3 are schematic diagrams of equivalent circuits of a pixel according to one or more embodiments;

FIGS. 4 and 5 are schematic cross-sectional views of a display device according to an embodiment; and

FIGS. 6 to 23 are schematic cross-sectional views of a display device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

One or more embodiments may be modified in various ways and may have various embodiments, and thus, specific embodiments are illustrated in the drawings and described in detail in the detailed description. Effects and features of one or more embodiments and methods for achieving the same could become clear by referring to embodiments described in detail below along with the drawings. However, one or more embodiments are not limited to the embodiments described below and may be implemented in various forms.

Hereinbelow, one or more embodiments are described in detail with reference to the accompanying drawings. When describing with reference to the drawings, identical or corresponding elements are assigned the same reference characters, and redundant descriptions thereof may be omitted.

In one or more embodiments below, terms such as first and second are used not in a limiting sense but for the purpose of distinguishing one element from another element.

In one or more embodiments below, singular expressions may include plural expressions, unless the context clearly dictates otherwise.

In one or more embodiments below, terms such as “comprise,” “include,” or “have” mean the presence of features or elements described in the specification, and do not preclude the possibility of adding one or more other features or elements.

In one or more embodiments below, when a part of a film, area, element, or the like is disposed over or on another part, it refers not only to a case where the part is directly on top of the other part, but also a case where another film, area, element, or the like is located therebetween.

In the drawings, for convenience of description, the sizes of elements may be exaggerated or reduced. For example, the size and thickness of each element shown in the drawings are shown arbitrarily for convenience of description, and thus, one or more embodiments are not necessarily limited to shown.

In one or more embodiments below, an x-axis, a y-axis, and a z-axis are not limited to the three axes in the Cartesian coordinate system, but can be interpreted in a broad sense including the same. For example, the x-axis, the y-axis, and the z-axis may be orthogonal to each other, but may also refer to directions that are not orthogonal to each other.

When an embodiment can be implemented differently, a specific process sequence may be performed differently from the described sequence. For example, two processes described in succession may be performed substantially at the same time, or may be performed in an order opposite to the described sequence.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

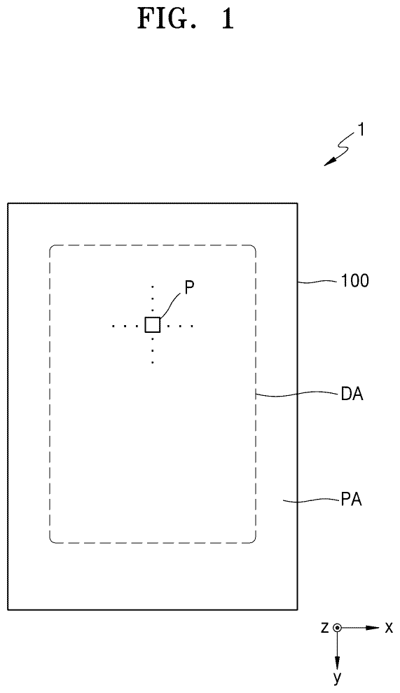

FIG. 1 is a plan view schematically illustrating a display device 1 according to an embodiment.

Referring to FIG. 1, the display device 1 may include a display area DA and a peripheral area PA that is a non-display area. Pixels P having organic light-emitting devices may be arranged in the display area DA to provide a certain image. The peripheral area PA does not provide an image and may include a scan driver and a data driver that are configured to provide electrical signals to be applied to the pixels P, and power lines configured to provide power such as a driving voltage and a common voltage.

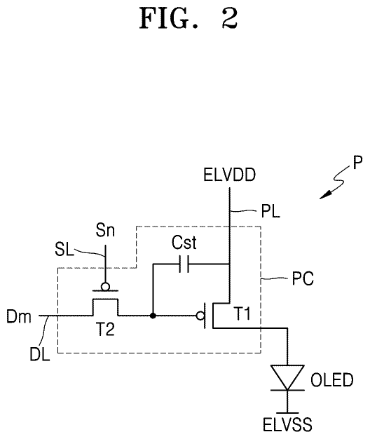

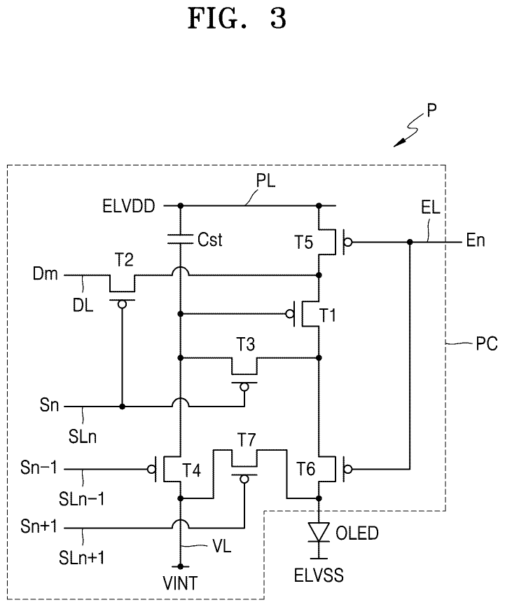

FIGS. 2 and 3 are schematic diagrams of equivalent circuits of a pixel P according to one or more embodiments.

Referring to FIG. 2, each pixel P may include a pixel circuit PC connected to a scan line SL and a data line DL, and an organic light-emitting device OLED connected to the pixel circuit PC.

The pixel circuit PC may include a driving thin-film transistor T1, a switching thin-film transistor T2, and a storage capacitor Cst. The switching thin-film transistor T2 may be connected to the scan line SL and the data line DL, and may transfer a data signal Dm received via the data line DL to the driving thin-film transistor T1 in response to a scan signal Sn received via the scan line SL.

The storage capacitor Cst may be connected to the switching thin-film transistor T2 and a driving voltage line PL and may store a voltage corresponding to a voltage difference between a voltage received from the switching thin-film transistor T2 and a driving voltage ELVDD supplied to the driving voltage line PL.

The driving thin-film transistor T1 may be connected to the driving voltage line PL and the storage capacitor Cst and may control a driving current flowing through the organic light-emitting device OLED from the driving voltage line PL to correspond to a voltage value stored in the storage capacitor Cst. The organic light-emitting device OLED may emit light having a certain luminance according to the driving current.

In FIG. 2, the pixel P may include two thin-film transistors and one storage thin-film transistor. However, one or more embodiments are not limited thereto.

Referring to FIG. 3, the pixel circuit PC may include driving and switching thin-film transistors T1 and T2, a compensation thin-film transistor T3, a first initialization thin-film transistor T4, a first emission control thin-film transistor T5, a second emission control thin-film transistor T6, and a second initialization thin-film transistor T7.

A drain electrode of the driving thin-film transistor T1 may be electrically connected to the organic light-emitting device OLED via the second emission control thin-film transistor T6. The driving thin-film transistor T1 may receive the data signal Dm in response to a switching operation of the switching thin-film transistor T2 and supply a driving current to the organic light-emitting device OLED.

A gate electrode of the switching thin-film transistor T2 may be connected to a first scan line SLn, and a source electrode of the switching thin-film transistor T2 may be connected to the data line DL. A drain electrode of the switching thin-film transistor T2 may be connected to the driving voltage line PL via the first emission control thin-film transistor T5 and to a source electrode of the driving thin-film transistor T1.

The switching thin-film transistor T2 may be turned on in response to a first scan signal Sn received via the first scan line SLn and may perform a switching operation for transferring the data signal Dm received via the data line DL to the source electrode of the driving thin-film transistor T1.

A gate electrode of the compensation thin-film transistor T3 may be connected to the first scan line SLn. A source electrode of the compensation thin-film transistor T3 may be connected to a pixel electrode of the organic light-emitting device OLED via the second emission control thin-film transistor T6 and to the drain electrode of the driving thin-film transistor T1. A drain electrode of the compensation thin-film transistor T3 may be connected any electrode of the storage capacitor Cst, a source electrode of the first initialization thin-film transistor T4, and a gate electrode of the driving thin-film transistor T1 together. The compensation thin-film transistor T3 may be turned on in response to the first scan signal Sn received via the first scan line SL and may connect the gate electrode of the gate electrode of the driving thin-film transistor T1 and the drain electrode of the driving thin-film transistor T1 to each other, to diode-connect the driving thin-film transistor T1.

A gate electrode of the first initialization thin-film transistor T4 may be connected to a second scan line SLn-1. A drain electrode of the first initialization thin-film transistor T4 may be connected to an initialization voltage line VL. A source electrode of the first initialization thin-film transistor T4 may be connected to any electrode of the storage capacitor Cst, the drain electrode of the compensation thin-film transistor T3, and the gate electrode of the driving thin-film transistor T1 together. The first initialization thin-film transistor T4 may be turned on in response to a second scan signal Sn-1 received via the second scan line SLn-1 and may perform an initialization operation for initializing a voltage in the gate electrode of the driving thin-film transistor T1 by transferring an initialization voltage VINT to the gate electrode of the driving thin-film transistor T1.

A gate electrode of the first emission control thin-film transistor T5 may be connected to an emission control line EL. A source electrode of the first emission control thin-film transistor T5 may be connected to the driving voltage line PL. A drain electrode of the first emission control thin-film transistor T5 may be connected to the source electrode of the driving thin-film transistor T1 and the drain electrode of the switching thin-film transistor T2.

A gate electrode of the second emission control thin-film transistor T6 may be connected to the emission control line EL. A source electrode of the second emission control thin-film transistor T6 may be connected to the drain electrode of the driving thin-film transistor T1 and the source electrode of the compensation thin-film transistor T3. The drain electrode of the second emission control thin-film transistor T6 may be electrically connected to the pixel electrode of the organic light-emitting device OLED. The first emission control thin-film transistor T5 and the second emission control thin-film transistor T6 may be simultaneously turned on in response to an emission control line En received via the emission control line EL so that the driving voltage ELVDD is transferred to the organic light-emitting device OLED, and a driving current flows through the organic light-emitting device OLED.

A gate electrode of the second initialization thin-film transistor T7 may be connected to a third scan line SLn+1. A source electrode of the second initialization thin-film transistor T7 may be connected to the pixel electrode of the organic light-emitting device OLED. A drain electrode of the second initialization thin-film transistor T7 may be connected to the initialization voltage line VL. The second initialization thin-film transistor T7 may be turned on in response to a third scan signal Sn+1 received via the third scan line SLn+1 and may initialize the pixel electrode of the organic light-emitting device OLED.

The other electrode of the storage capacitor Cst may be connected to the driving voltage line PL. An electrode of the storage capacitor Cst may be connected to the gate electrode of the driving thin-film transistor T1, the drain electrode of the compensation thin-film transistor T3, and the source electrode of the first initialization thin-film transistor T4 together.

A counter electrode of the organic light-emitting device OLED may receive a common power voltage ELVSS. The organic light-emitting device OLED may receive a driving current from the driving thin-film transistor T1 and emit light.

The pixel circuit PC is not limited to the number of thin-film transistors, the number of storage capacitors, and the circuit design described with reference to FIGS. 2 and 3, and the numbers and the circuit design may be variously modified.

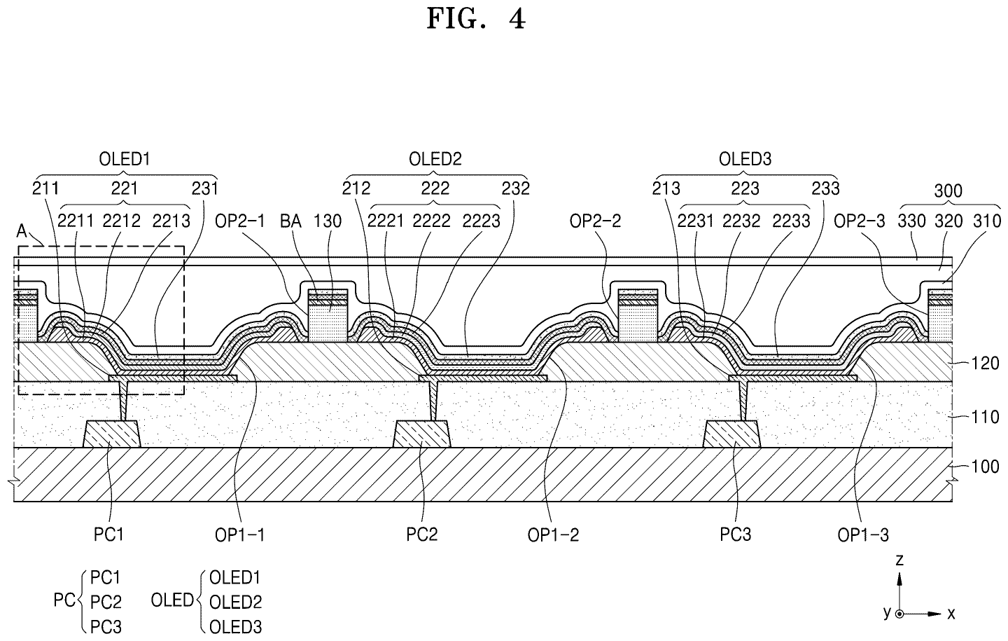

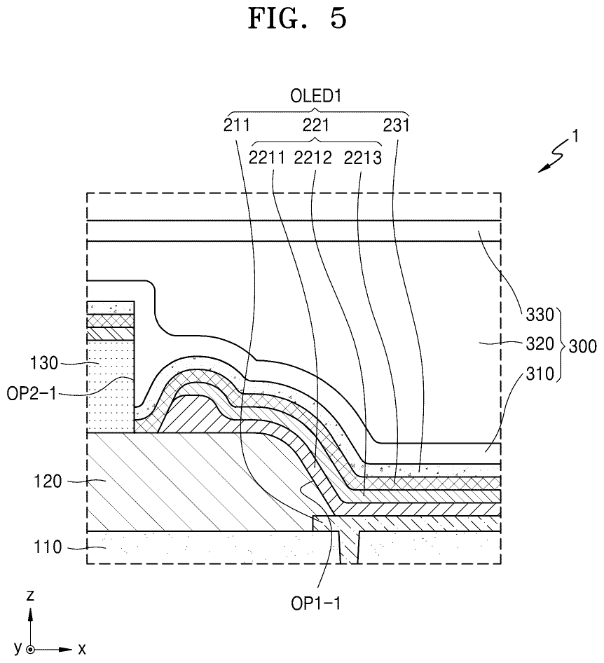

FIGS. 4 and 5 are schematic cross-sectional views of the display device 1 according to an embodiment. For example, FIG. 5 is an enlarged cross-sectional view of region A of FIG. 3.

Referring to FIGS. 4 and 5, the display device 1 may include a substrate 100, a circuit element layer 110, the organic light-emitting device OLED, a bank layer 120, a heating electrode 130, a barrier layer BA, and/or a thin-film encapsulation layer 300.

The substrate 100 may include various materials such as a glass material or a plastic material such as polyethylene terephthalate (PET), polyethylene naphthalate (PEN), and polyimide. In case that the substrate 100 includes a plastic material, flexibility may be improved compared to a case that the substrate 100 includes a glass material.

The circuit element layer 110 including the pixel circuit PC may be provided on the substrate 100. The pixel circuit PC may include a thin-film transistor and a storage capacitor as described above with reference to FIGS. 2 and 3. Layers included in the thin-film transistor and the storage capacitor, for example, a semiconductor layer and electrode layers, may be disposed with an insulating layer therebetween. The pixel circuit PC may include one or more pixel circuits. The pixel circuits PC may be arranged to be spaced apart from each other. For example, the pixel circuit PC may include a first pixel circuit PC1, a second pixel circuit PC2, and a third pixel circuit PC3, which are arranged to be spaced apart from each other.

The organic light-emitting device OLED may be disposed on the circuit element layer 110 and electrically connected to the pixel circuit PC. The organic light-emitting device OLED may include one or more organic light-emitting devices. The organic light-emitting devices OLED may be arranged to be spaced apart from each other. For example, the organic light-emitting device OLED may include a first organic light-emitting device OLED1, a second organic light-emitting device OLED2, and a third organic light-emitting device OLED3, which are arranged to be spaced apart from each other.

The first organic light-emitting device OLED1 may include a first pixel electrode 211, a first intermediate layer 221, and a first common electrode 231. The second organic light-emitting device OLED2 may include a second pixel electrode 212, a second intermediate layer 222, and a second common electrode 232. The third organic light-emitting device OLED3 may include a third pixel electrode 213, a third intermediate layer 223, and a third common electrode 233.

The first to third pixel electrodes 211, 212, and 213 may be disposed on the circuit element layer 110 to be spaced apart from each other. The first to third pixel electrodes 211, 212, and 213 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the first to third pixel electrodes 211, 212, and 213 may include a reflective film including, for example, silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first to third pixel electrodes 211, 212, and 213 may further include a film including, for example, ITO, IZO, ZnO, or In₂O₃ over/under the reflective film described above.

The bank layer 120 may be disposed on the circuit element layer 110. The bank layer 120 may be disposed on the first to third pixel electrodes 211, 212, and 213. The bank layer 120 may cover ends of the first to third pixel electrodes 211, 212, and 213. The bank layer 120 may include first-1 opening OP1-1 exposing a part of the first pixel electrode 211, a first-2 opening OP1-2 exposing a part of the second pixel electrode 212, and a first-3 opening OP1-3 exposing a part of the third pixel electrode 213. A central portion of the first pixel electrode 211 may be exposed by the first-1 opening OP1-1, a central portion of the second pixel electrode 212 may be exposed by the first-2 opening OP1-2, and a central portion of the third pixel electrode 213 may be exposed by the first-3 opening OP1-3.

The bank layer 120 may include an organic material or an inorganic material. In an embodiment, in case that the bank layer 120 has an organic material, the bank layer 120 may include one or more organic insulating materials selected from the group consisting of polyimide, polyamide, an acrylic resin layer, benzocyclobutene, and a phenolic resin layer. In another embodiment, in case that the bank layer 120 has an inorganic material, the bank layer 120 may include one or more layers including silicon oxide (SiOₓ), silicon nitride (SiNₓ), and/or silicon oxynitride (SiON). In case that the bank layer 120 has an inorganic material, an outgassing phenomenon may be reduced and the durability of the display device 1 may be improved.

The first intermediate layer 221 may be accommodated in the first-1 opening OP1-1. The first intermediate layer 221 may include a first-1 functional layer 2211, a first emission layer 2212, and a first-2 functional layer 2213. The first-1 functional layer 2211 may be disposed on the first pixel electrode 211 and accommodated in the first-1 opening OP1-1. The first-1 functional layer 2211 may be in contact with the first pixel electrode 211. The first emission layer 2212 may be disposed on the first pixel electrode 211 and accommodated in the first-1 opening OP1-1. The first emission layer 2212 may be disposed on the first-1 functional layer 2211 to be in contact with the first-1 functional layer 2211. The first-2 functional layer 2213 may be disposed on the first pixel electrode 211 and accommodated in the first-1 opening OP1-1. The first-2 functional layer 2213 may be disposed on the first emission layer 2212 to be in contact with the first emission layer 2212.

The second intermediate layer 222 may be accommodated in the first-2 opening OP1-2. The second intermediate layer 222 may include a second-1 functional layer 2221, a second emission layer 2222, and a second-2 functional layer 2223. The second-1 functional layer 2221 may be disposed on the second pixel electrode 212 and accommodated in the first-2 opening OP1-2. The second-1 functional layer 2221 may be in contact with the second pixel electrode 212. The second emission layer 2222 may be disposed on the second pixel electrode 212 and accommodated in the first-2 opening OP1-2. The second emission layer 2222 may be disposed on the second-1 functional layer 2221 to be in contact with the second-1 functional layer 2221. The second-2 functional layer 2223 may be disposed on the second pixel electrode 212 and accommodated in the first-2 opening OP1-2. The second-2 functional layer 2223 may be disposed on the second emission layer 2222 to be in contact with the second emission layer 2222.

The third intermediate layer 223 may be accommodated in the first-3 opening OP1-3. The third intermediate layer 223 may include a third-1 functional layer 2231, a third emission layer 2232, and a third-2 functional layer 2233. The third-1 functional layer 2231 may be disposed on the third pixel electrode 213 and accommodated in the first-3 opening OP1-3. The third-1 functional layer 2231 may be in contact with the third pixel electrode 213. The third emission layer 2232 may be disposed on the third pixel electrode 213 and accommodated in the first-3 opening OP1-3. The third emission layer 2232 may be disposed on the third-1 functional layer 2231 to be in contact with the third-1 functional layer 2231. The third-2 functional layer 2233 may be disposed on the third pixel electrode 213 and accommodated in the first-3 opening OP1-3. The third-2 functional layer 2233 may be disposed on the third emission layer 2232 to be in contact with the third emission layer 2232.

The first-1 to third-1 functional layers 2211, 2221, and 2231 may include, for example, a hole transport layer (HTL) or an HTL with a hole injection layer (HIL). In an embodiment, the first to third emission layers 2212, 2222, and 2232 may include a polymer or low-molecular weight organic material emitting light of a color. As another example, the first to third emission layers 2212, 2222, and 2232 may include an inorganic light-emitting material or quantum dots. The first-2 to third-2 functional layers 2213, 2223, and 2233 may include an electron transport layer (ETL) and/or an electron injection layer (EIL).

The first emission layer 2212, the second emission layer 2222, and the third emission layer 2232 may emit light of different colors. For example, the first emission layer 2212 may emit red light, the second emission layer 2222 may emit green light, and the third emission layer 2232 may emit blue light.

The first common electrode 231 may be disposed on the bank layer 120. The first common electrode 231 may be accommodated in the first-1 opening OP1-1 so as to be disposed on the first emission layer 2212. The first common electrode 231 may overlap the first pixel electrode 211.

The second common electrode 232 may be disposed on the bank layer 120. The second common electrode 232 may be accommodated in the first-2 opening OP1-2 so as to be disposed on the second emission layer 2222. The second common electrode 232 may overlap the second pixel electrode 212.

The third common electrode 233 may be disposed on the bank layer 120. The third common electrode 233 may be accommodated in the first-3 opening OP1-3 so as to be disposed on the third emission layer 2232. The third common electrode 233 may overlap the third pixel electrode 213. The first common electrode 231, the second common electrode 232, and the third common electrode 233 may be spaced apart from each other.

The first to third common electrodes 231, 232, and 233 may include a conductive material having a low work function. For example, the first to third common electrodes 231, 232, and 233 may include a (semi-)transparent layer including Ag, Mg, Al, Pt, Pd, Au, Ni, Nd, Ir, Cr, lithium (Li), calcium (Ca), or an alloy thereof. As another example, the first to third common electrodes 231, 232, and 233 may further include a layer including ITO, IZO, ZNO, or In₂O₃ on the (semi-)transparent layer including the materials described above.

The heating electrode 130 may be disposed on the bank layer 120. The heating electrode 130 may include a second-1 opening OP2-1, a second-2 opening OP2-2, and a second-3 opening OP2-3, which are arranged to be spaced apart from each other. The second-1 opening OP2-1 may overlap the first-1 opening OP1-1, the second-2 opening OP2-2 may overlap the first-2 opening OP1-2, and the second-3 opening OP2-3 may overlap the first-3 opening OP1-3. For example, a width of the second-1 opening OP2-1 may be greater than a width of the first-1 opening OP1-1, a width of the second-2 opening OP2-2 may be greater than a width of the first-2 opening OP1-2, and a width of the second-3 opening OP2-3 may be greater than a width of the first-3 opening OP1-3.

The heating electrode 130 may include at least one of molybdenum (Mo), Al, Pt, Pd, Ag, Mg, Au, Ni, Nd, Ir, Cr, Ca, titanium (Ti), tungsten (W), and copper (Cu) and may include one or more layers of the materials described above.

The first-1 functional layer 2211, the first emission layer 2212, the first-2 functional layer 2213, and the first common electrode 231 disposed on the bank layer 120 may be accommodated in the second-1 opening OP2-1. The first-1 functional layer 2211 may be between the first pixel electrode 211 and the first emission layer 2212, and the first-2 functional layer 2213 may be between the first emission layer 2212 and the first common electrode 231.

The first-1 functional layer 2211 and the first emission layer 2212 may be spaced apart from the heating electrode 130. The first-2 functional layer 2213 and the first common electrode 231 may cover the first-1 functional layer 2211 and the first emission layer 2212. The first-2 functional layer 2213 and the first common electrode 231 may be in contact with the heating electrode 130. Ends of the first-1 functional layer 2211 and the first emission layer 2212 may be provided to be convex.

The second-1 functional layer 2221, the second emission layer 2222, the second-2 functional layer 2223, and the second common electrode 232 disposed over the bank layer 120 may be accommodated in the first-2 opening OP1-2. The second-1 functional layer 2221 may be between the second pixel electrode 212 and the second emission layer 2222, and the second-2 functional layer 2223 may be between the second emission layer 2222 and the second common electrode 232.

The second-1 functional layer 2221 and the second emission layer 2222 may be spaced apart from the heating electrode 130. The second-2 functional layer 2223 and the second common electrode 232 may cover the second-1 functional layer 2221 and the second emission layer 2222. The second-2 functional layer 2223 and the second common electrode 232 may be in contact with the heating electrode 130. Ends of the second-1 functional layer 2221 and the second emission layer 2222 may be provided to be convex.

The third-1 functional layer 2231, the third emission layer 2232, the third-2 functional layer 2233, and the third common electrode 233 disposed over the bank layer 120 may be accommodated in the first-3 opening OP1-3. The third-1 functional layer 2231 may be between the third pixel electrode 213 and the third emission layer 2232, and the third-2 functional layer 2233 may be between the third emission layer 2232 and the third common electrode 233.

The third-1 functional layer 2231 and the third emission layer 2232 may be spaced apart from the heating electrode 130. The third-2 functional layer 2233 and the third common electrode 233 may cover the third-1 functional layer 2231 and the third emission layer 2232. The third-2 functional layer 2233 and the third common electrode 233 may be in contact with the heating electrode 130. Ends of the third-1 functional layer 2231 and the third emission layer 2232 may be provided to be convex.

The barrier layer BA may be disposed on the heating electrode 130. In a plan view, a shape of the barrier layer BA may correspond to a shape of the heating electrode 130. The barrier layer BA may include openings corresponding to the second-1 opening OP2-1, the second-2 opening OP2-2, and the second-3 opening OP2-3 of the heating electrode 130.

The barrier layer BA may include an insulating material. For example, the barrier layer BA may include one or more layers including an inorganic material such as silicon nitride (SiNₓ), silicon oxide (SiO₂), and/or silicon oxynitride (SiON).

The first-2 functional layer 2213, the second-2 functional layer 2223, and the third-2 functional layer 2233 may be common layers and may include the same material. The first common electrode 231, the second common electrode 232, and the third common electrode 233 may be common layers and may include the same material. On the barrier layer BA, the same material as the first-2 functional layer 2213, the second-2 functional layer 2223, and the third-2 functional layer 2233 may be disposed, and thereon, the same material as the first common electrode 231, the second common electrode 232, and the third common electrode 233 may be disposed.

The thin-film encapsulation layer 300 may be disposed on the organic light-emitting device OLED, the heating electrode 130, and the barrier layer BA. The thin-film encapsulation layer 300 may be in contact with the first common electrode 231, the second common electrode 232, and the third common electrode 233.

The thin-film encapsulation layer 300 may include at least one inorganic film and at least one organic film. For example, the thin-film encapsulation layer 300 may include a first inorganic encapsulation layer 310, an organic encapsulation layer 320, and a second inorganic encapsulation layer 330, which are sequentially stacked, but is not limited thereto and may have various configurations.

In an embodiment, the first inorganic encapsulation layer 310 and the second inorganic encapsulation layer 330 may be formed to include one or more materials selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and SiON.

In an embodiment, the organic encapsulation layer 320 may be formed to include one or more materials selected from the group consisting of an acryl-based resin layer, a methacryl-based resin layer, polyisoprene, a vinyl-based resin layer, a urethane-based resin layer, a cellulose-based resin layer, and a perylene-based resin layer.

In FIG. 4, the thin-film encapsulation layer 300 may be formed on the organic light-emitting devices OLED. However, one or more embodiments are not limited thereto. In other words, the display device 1 may include a sealing substrate (not shown) instead of the thin-film encapsulation layer 300. The sealing substrate (not shown) may be bonded to the substrate 100 by sealing glass frit or other sealing member to block external moisture, air, or the like.

In the embodiment, various functional layers such as a polarization layer, a color filter layer, and a touchscreen layer may be further disposed on the thin-film encapsulation layer 300.

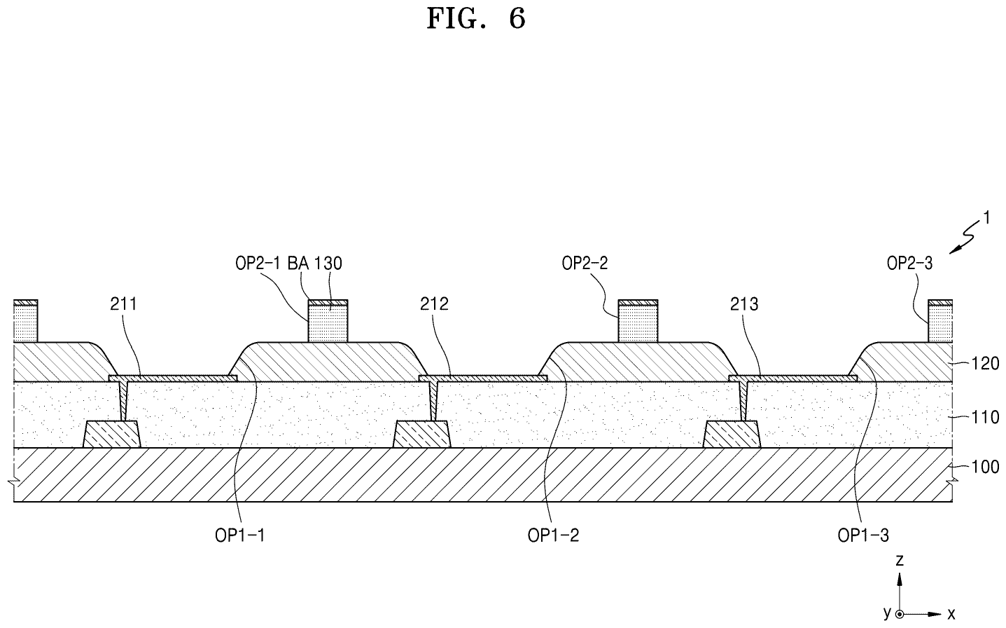

FIGS. 6 to 23 are schematic cross-sectional views of the display device 1 according to an embodiment.

Referring to FIGS. 6 to 23, a method of manufacturing the display device 1 can be seen.

In FIGS. 6 to 23, the same reference characters as FIGS. 1 to 5 denote the same member, and redundant descriptions thereof are omitted.

First, referring to FIG. 6, the method of manufacturing the display device 1 may include disposing the circuit element layer 110 on the substrate 100, disposing the first pixel electrode 211, the second pixel electrode 212, and the third pixel electrode 213 on the circuit element layer 110, disposing the bank layer 120 on the circuit element layer 110, disposing the heating electrode 130 on the bank layer 120, and disposing the barrier layer BA on the heating electrode 130.

In this case, the bank layer 120 may include first-1 opening OP1-1 exposing a part of the first pixel electrode 211, a first-2 opening OP1-2 exposing a part of the second pixel electrode 212, and a first-3 opening OP1-3 exposing a part of the third pixel electrode 213.

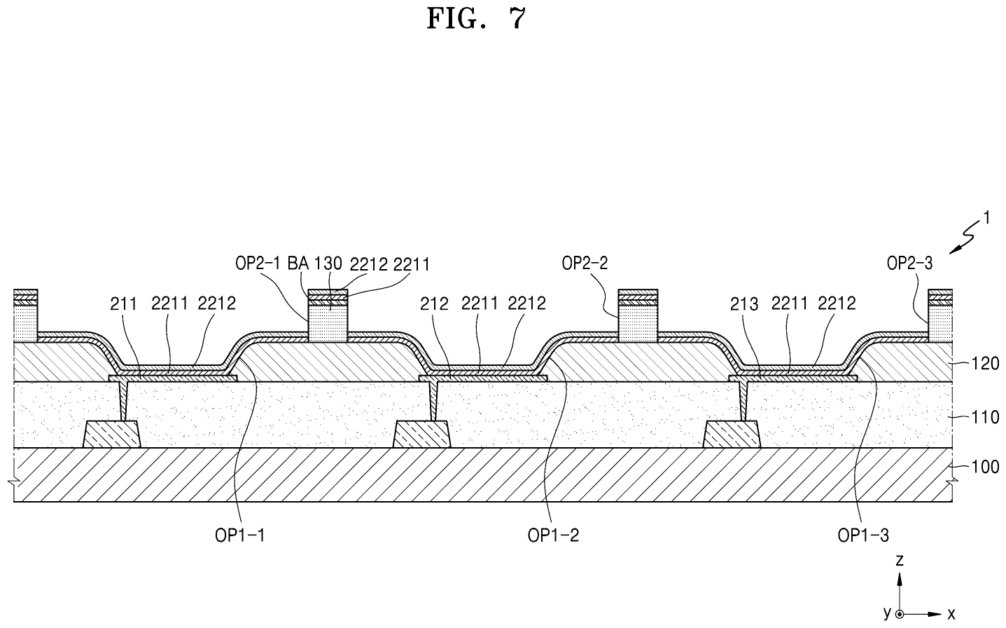

Referring to FIG. 7, the method of manufacturing the display device 1 may include disposing the first-1 functional layer 2211 on the first pixel electrode 211, the second pixel electrode 212, and the third pixel electrode 213, and disposing the first emission layer 2212 on the first pixel electrode 211, the second pixel electrode 212, and the third pixel electrode 213.

A deposition material may be sprayed toward the substrate 100 from over the display device 1 and may form the first-1 functional layer 2211. The first-1 functional layer 2211 may be disposed on the first pixel electrode 211, the second pixel electrode 212, the third pixel electrode 213, the bank layer 120, and the barrier layer BA. In the disposing of the first-1 functional layer 2211, the first-1 functional layer 2211 may be in contact with the heating electrode 130.

A deposition material may be sprayed toward the substrate 100 from over the display device 1 and may form the first emission layer 2212. The first emission layer 2212 may be disposed on the first-1 functional layer 2211, the bank layer 120, and the barrier layer BA. In the disposing of the first emission layer 2212, the first emission layer 2212 may be in contact with the heating electrode 130.

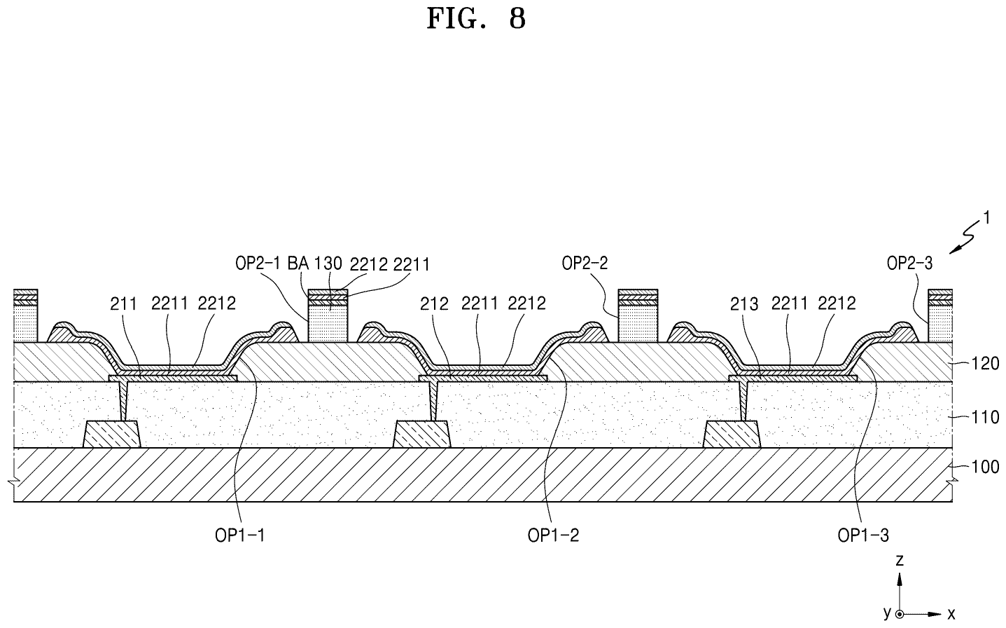

Referring to FIG. 8, the method of manufacturing the display device 1 may include performing a first Joule heating on the heating electrode 130.

The heating electrode 130 may be connected to a heating line, and in case that a current flows by a voltage applied via the heating line, Joule heat may be generated. The heating electrode 130 may volatilize or decompose an organic layer by generating the Joule heat.

In the performing of the first Joule heating on the heating electrode 130, parts of the first-1 functional layer 2211 and the first emission layer 2212 in contact with the heating electrode 130 may be removed. Accordingly, in the performing of the first Joule heating on the heating electrode 130, the first-1 functional layer 2211 and the first emission layer 2212 may be spaced apart from the heating electrode 130. For this reason, in the performing of the first Joule heating on the heating electrode 130, ends of the first-1 functional layer 2211 and the first emission layer 2212 may be formed to be convex.

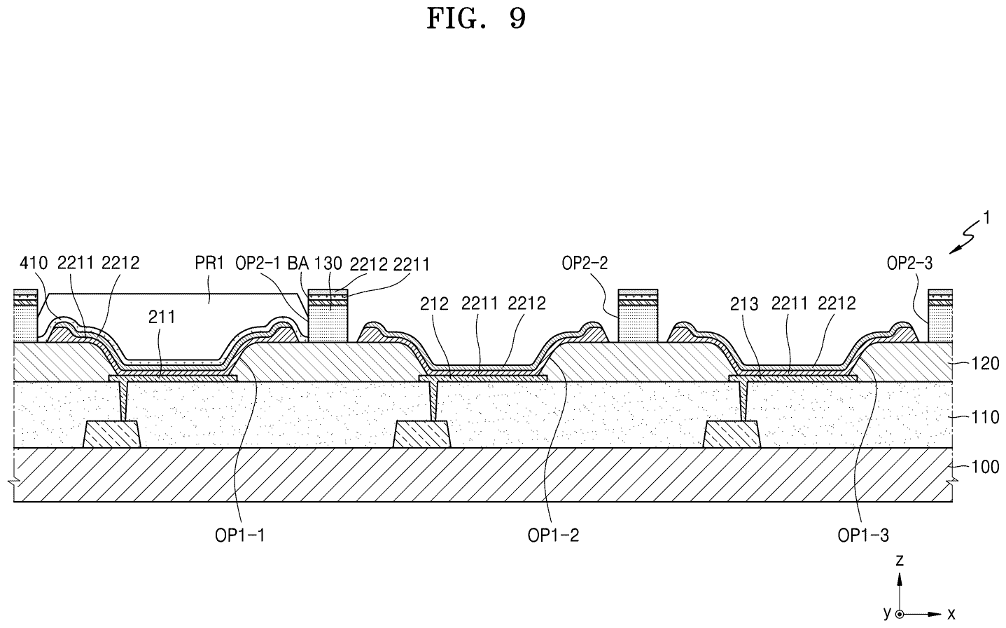

Referring to FIG. 9, the method of manufacturing the display device 1 may include disposing a first sacrificial layer 410 on the first emission layer 2212 arranged in the first-1 opening OP1-1, and disposing a first photoresist layer PR1 on the first sacrificial layer 410.

The first sacrificial layer 410 may be arranged in the first-1 opening OP1-1 and the second-1 opening OP2-1. The first sacrificial layer 410 may cover the first-1 functional layer 2211 and the first emission layer 2212 arranged in the first-1 opening OP1-1 and the second-1 opening OP2-1. The first sacrificial layer 410 may be in contact with the heating electrode 130. The first photoresist layer PR1 may be arranged in the second-1 opening OP2-1 and may cover the first sacrificial layer 410. Accordingly, the first sacrificial layer 410 may be sealed by the first photoresist layer PR1. For example, the first sacrificial layer 410 may include Al or Ag.

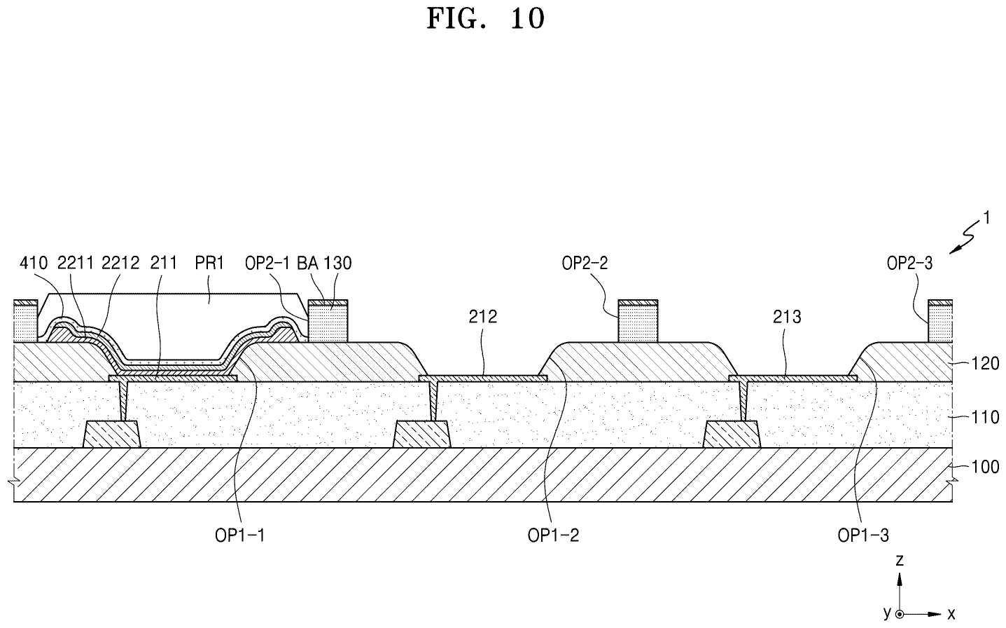

Referring to FIG. 10, the method of manufacturing the display device 1 may include removing the first-1 functional layer 2211 and the first emission layer 2212 that are disposed on the second pixel electrode 212 and the third pixel electrode 213.

The first-1 functional layer 2211 and the first emission layer 2212, which do not overlap the first photoresist layer PR1, may be dry-etched or wet-etched. For example, the first-1 functional layer 2211 and the first emission layer 2212 accommodated in the first-2 opening OP1-2 and the second-2 opening OP2-2 may be removed. The first-1 functional layer 2211 and the first emission layer 2212 accommodated in the first-3 opening OP1-3 and the second-3 opening OP2-3 may be removed. The first-1 functional layer 2211 and the first emission layer 2212 disposed on the heating electrode 130 may be removed. The first-1 functional layer 2211, the first emission layer 2212, and the first sacrificial layer 410, which overlap the first photoresist layer PR1, may not be removed.

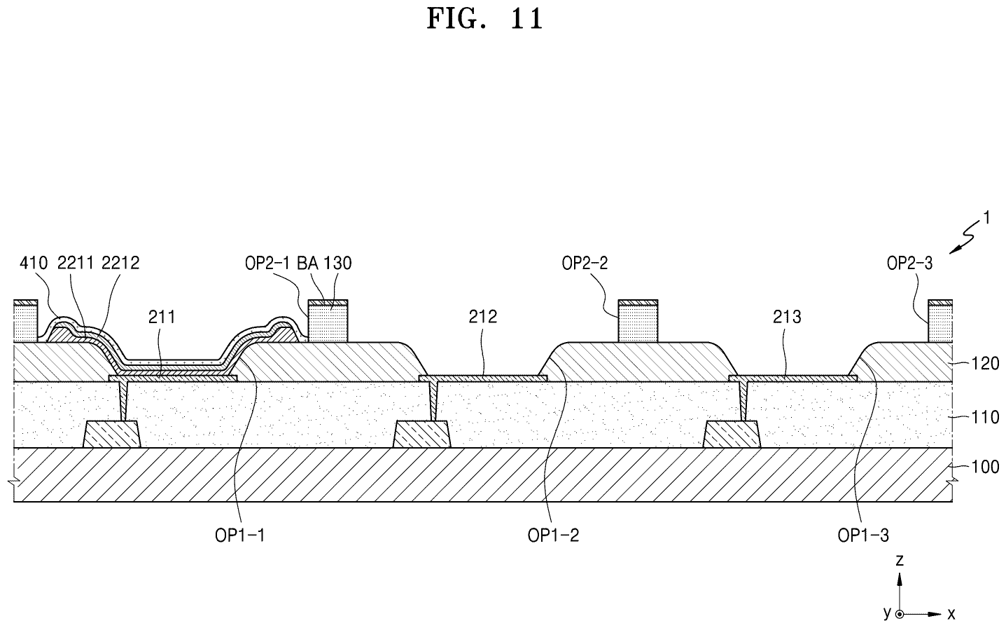

Referring to FIG. 11, the method of manufacturing the display device 1 may include removing the first photoresist layer PR1. Accordingly, the first sacrificial layer 410 may be exposed to the outside.

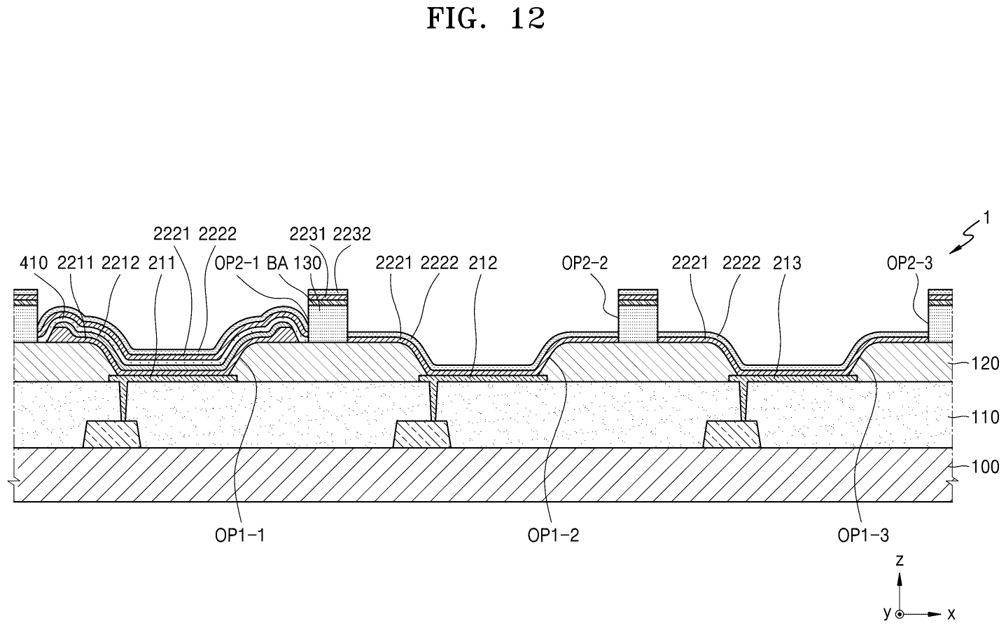

Referring to FIG. 12, the method of manufacturing the display device 1 may include disposing the second-1 functional layer 2221 on the first sacrificial layer 410, the second pixel electrode 212, and the third pixel electrode 213, and disposing the second emission layer 2222 on the first sacrificial layer 410, the second pixel electrode 212, and the third pixel electrode 213.

A deposition material may be sprayed toward the substrate 100 from over the display device 1 and may form the second-1 functional layer 2221. The second-1 functional layer 2221 may be disposed on the first sacrificial layer 410, the second pixel electrode 212, the third pixel electrode 213, the bank layer 120, and the barrier layer BA. In the disposing of the second-1 functional layer 2221, the second-1 functional layer 2221 may be in contact with the heating electrode 130.

A deposition material may be sprayed toward the substrate 100 from over the display device 1 and may form the second emission layer 2222. The second emission layer 2222 may be disposed on the second-1 functional layer 2221, the bank layer 120, and the barrier layer BA. In the disposing of the second emission layer 2222, the second emission layer 2222 may be in contact with the heating electrode 130.

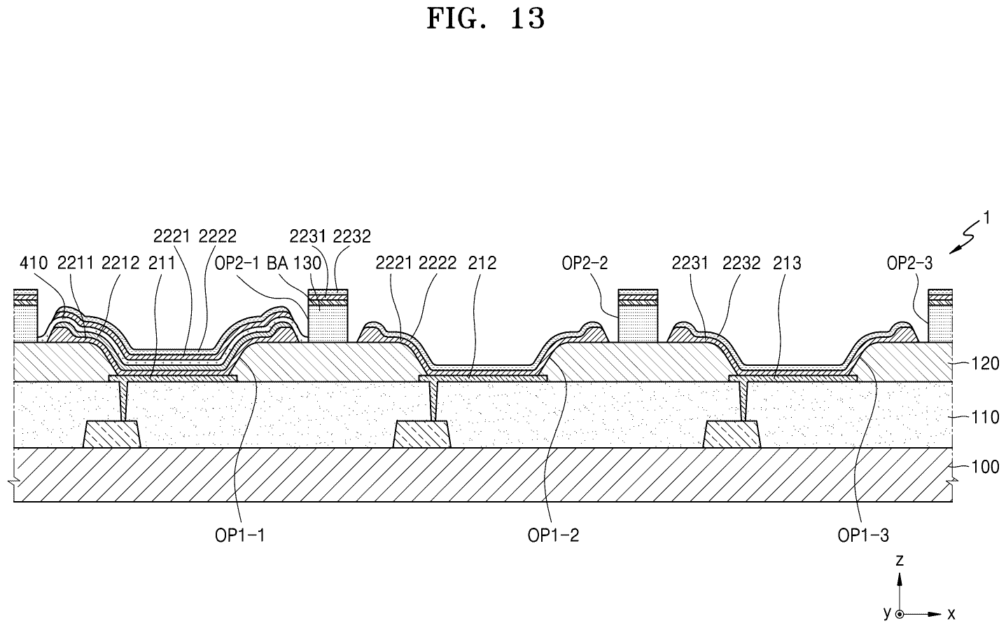

Referring to FIG. 13, the method of manufacturing the display device 1 may include performing a second Joule heating on the heating electrode 130.

The heating electrode 130 may be connected to a heating line, and in case that a current flows by a voltage applied via the heating line, Joule heat may be generated. The heating electrode 130 may volatilize or decompose an organic layer by generating the Joule heat.

In the performing of the second Joule heating on the heating electrode 130, parts of the second-1 functional layer 2221 and the second emission layer 2222 in contact with the heating electrode 130 may be removed. Accordingly, in the performing of the second Joule heating on the heating electrode 130, the second-1 functional layer 2221 and the second emission layer 2222 may be spaced apart from the heating electrode 130. For this reason, in the performing of the second Joule heating on the heating electrode 130, ends of the second-1 functional layer 2221 and the second emission layer 2222 may be formed to be convex.

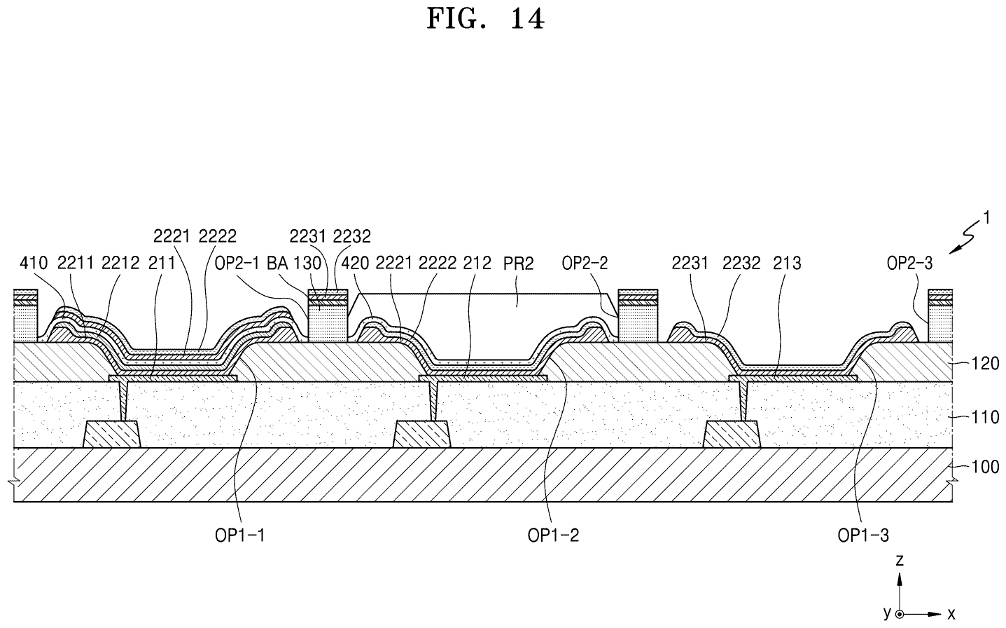

Referring to FIG. 14, the method of manufacturing the display device 1 may include disposing a second sacrificial layer 420 on the second emission layer 2222 arranged in the second-1 opening OP2-1, and disposing a second photoresist layer PR2 on the second sacrificial layer 420.

The second sacrificial layer 420 may be arranged in the first-2 opening OP1-2 and the second-2 opening OP2-2. The second sacrificial layer 420 may cover the second-1 functional layer 2221 and the second emission layer 2222 arranged in the first-2 opening OP1-2 and the second-2 opening OP2-2. The second sacrificial layer 420 may be in contact with the heating electrode 130. The second photoresist layer PR2 may be arranged in the second-2 opening OP2-2 and may cover the second sacrificial layer 420. Accordingly, the second sacrificial layer 420 may be sealed by the second photoresist layer PR2. For example, the second sacrificial layer 420 may include Al or Ag.

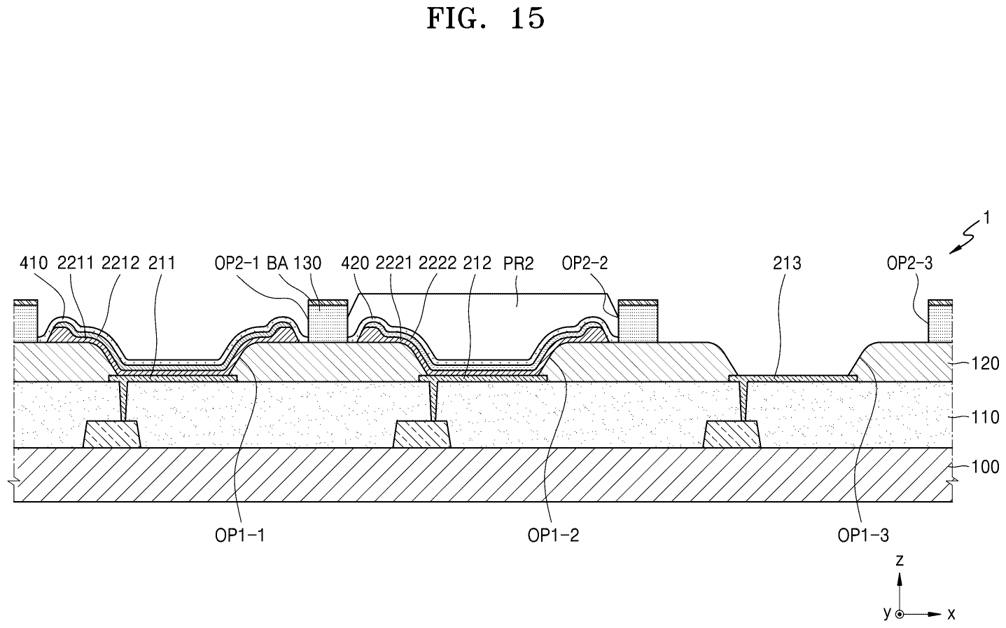

Referring to FIG. 15, the method of manufacturing the display device 1 may include removing the second-1 functional layer 2221 and the second emission layer 2222 that are disposed on the first pixel electrode 211 and the third pixel electrode 213.

The second-1 functional layer 2221 and the second emission layer 2222, which do not overlap the second photoresist layer PR2, may be dry-etched or wet-etched. For example, the second-1 functional layer 2221 and the second emission layer 2222 accommodated in the first-1 opening OP1-1 and the second-1 opening OP2-1 may be removed. The second-1 functional layer 2221 and the second emission layer 2222 accommodated in the first-3 opening OP1-3 and the second-3 opening OP2-3 may be removed. The second-1 functional layer 2221 and the second emission layer 2222 disposed on the heating electrode 130 may be removed. The second-1 functional layer 2221, the second emission layer 2222, and the second sacrificial layer 420, which overlap the second photoresist layer PR2, may not be removed. In this case, the first-1 functional layer 2211 and the first emission layer 2212 may be covered by the first sacrificial layer 410, and thus, the first-1 functional layer 2211 and the first emission layer 2212 may not be removed.

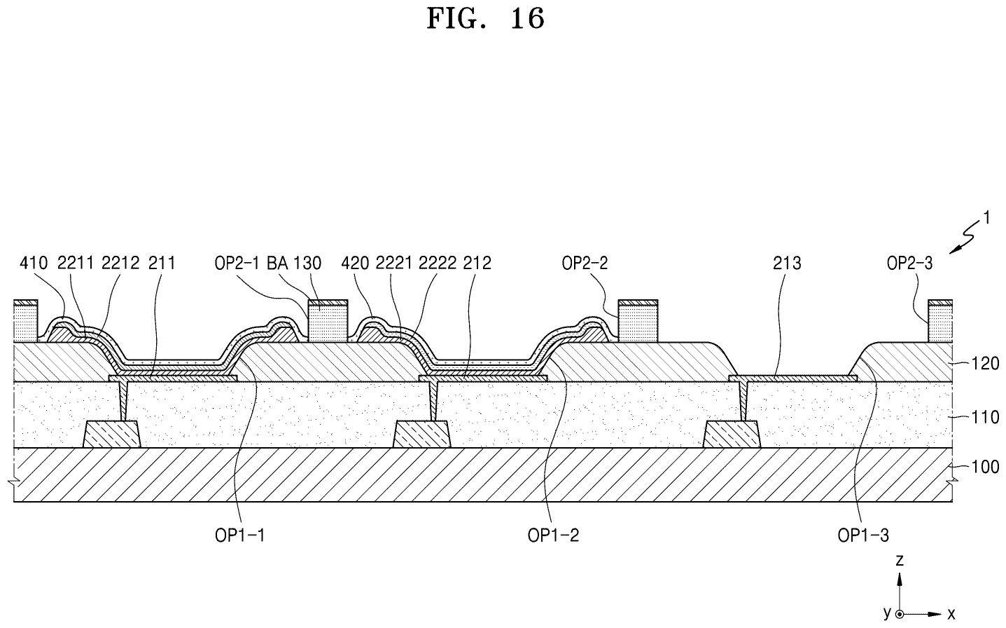

Referring to FIG. 16, the method of manufacturing the display device 1 may include removing the second photoresist layer PR2. Accordingly, the second sacrificial layer 420 may be exposed to the outside.

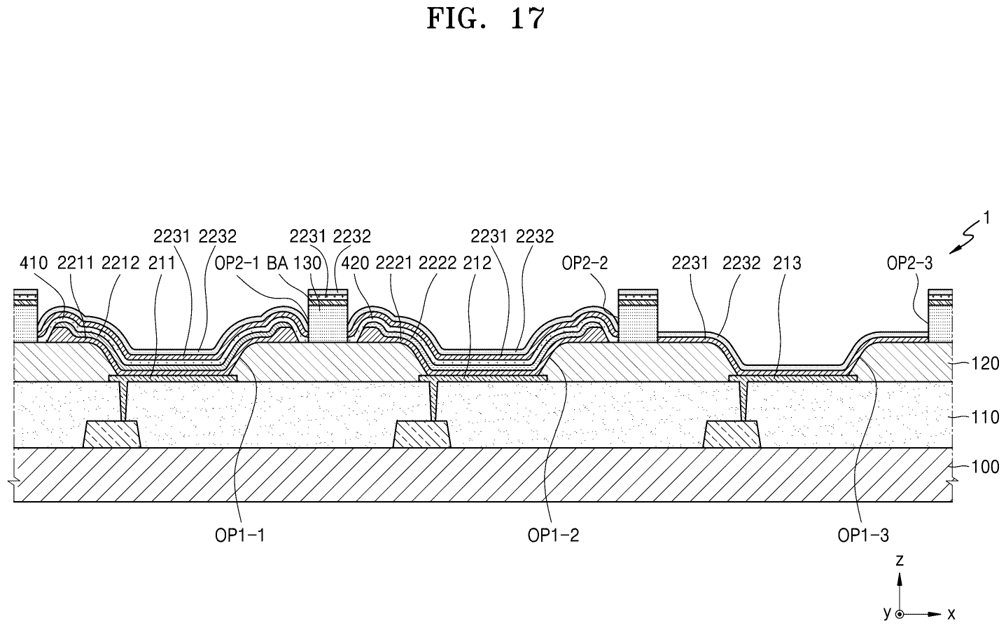

Referring to FIG. 17, the method of manufacturing the display device 1 may include disposing the third-1 functional layer 2231 on the first sacrificial layer 410, the second sacrificial layer 420, and the third pixel electrode 213, and disposing the third emission layer 2232 on the first sacrificial layer 410, the second sacrificial layer 420, and the third pixel electrode 213.

A deposition material may be sprayed toward the substrate 100 from over the display device 1 and may form the third-1 functional layer 2231. The third-1 functional layer 2231 may be disposed on the first sacrificial layer 410, the second sacrificial layer 420, the third pixel electrode 213, the bank layer 120, and the barrier layer BA. In the disposing of the third-1 functional layer 2231, the third-1 functional layer 2231 may be in contact with the heating electrode 130.

A deposition material may be sprayed toward the substrate 100 from over the display device 1 and may form the third emission layer 2232. The third emission layer 2232 may be disposed on the third-1 functional layer 2231, the bank layer 120, and the barrier layer BA. In the disposing of the third emission layer 2232, the third emission layer 2232 may be in contact with the heating electrode 130.

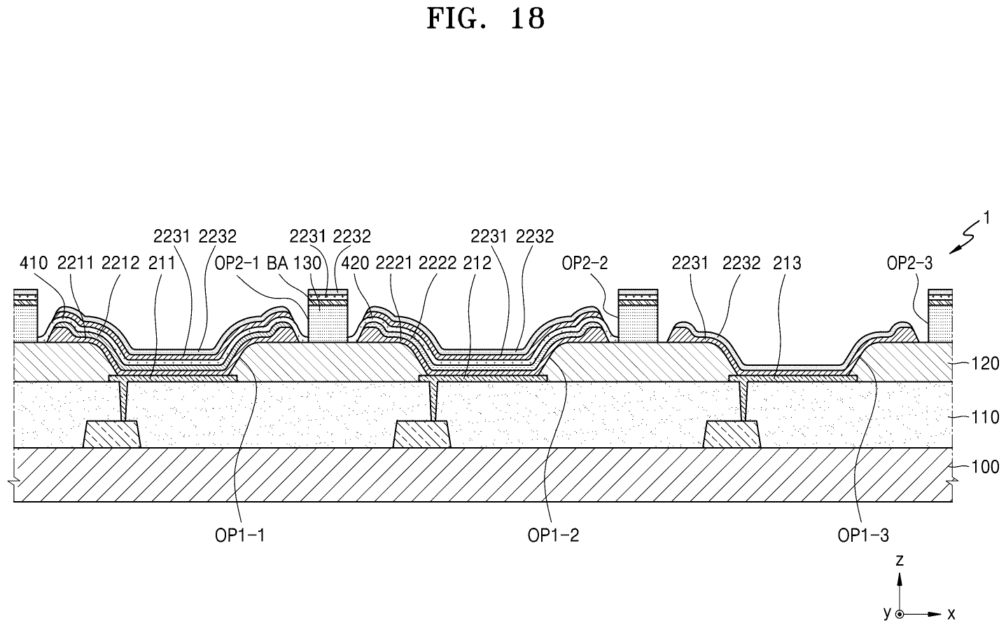

Referring to FIG. 18, the method of manufacturing the display device 1 may include performing a third Joule heating on the heating electrode 130.

The heating electrode 130 may be connected to a heating line, and in case that a current flows by a voltage applied via the heating line, Joule heat may be generated. The heating electrode 130 may volatilize or decompose an organic layer by generating the Joule heat.

In the performing of the third Joule heating on the heating electrode 130, parts of the third-1 functional layer 2231 and the third emission layer 2232 in contact with the heating electrode 130 may be removed. Accordingly, in the performing of the third Joule heating on the heating electrode 130, the third-1 functional layer 2231 and the third emission layer 2232 may be spaced apart from the heating electrode 130. For this reason, in the performing of the third Joule heating on the heating electrode 130, ends of the third-1 functional layer 2231 and the third emission layer 2232 may be formed to be convex.

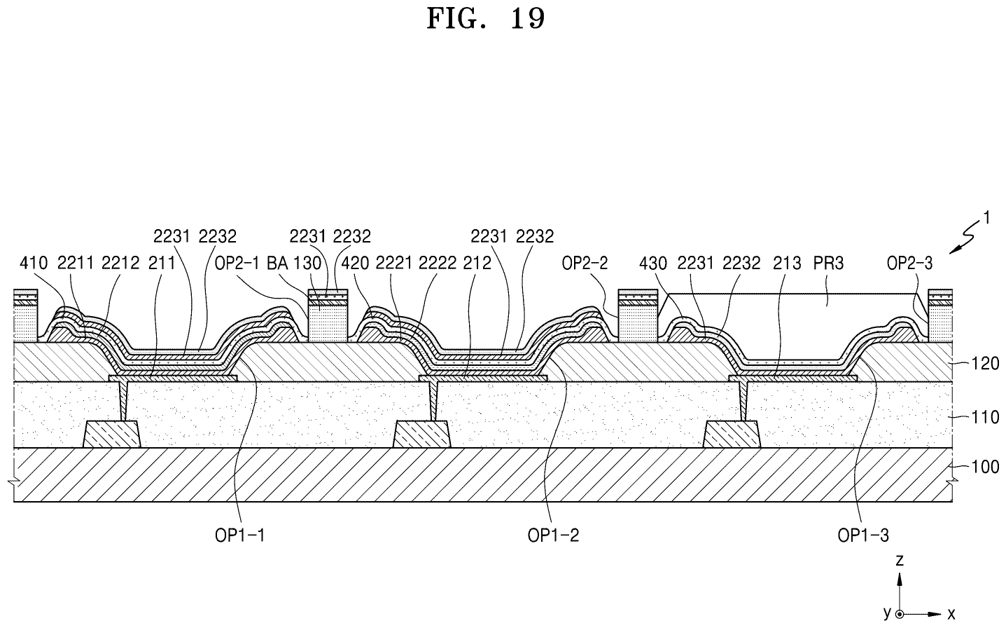

Referring to FIG. 19, the method of manufacturing the display device 1 may include disposing a third sacrificial layer 430 on the third emission layer 2232 arranged in the second-3 opening OP2-3, and disposing a third photoresist layer PR3 on the third sacrificial layer 430.

The third sacrificial layer 430 may be arranged in the first-3 opening OP1-3 and the second-3 opening OP2-3. The third sacrificial layer 430 may cover the third-1 functional layer 2231 and the third emission layer 2232 arranged in the first-3 opening OP1-3 and the second-3 opening OP2-3. The third sacrificial layer 430 may be in contact with the heating electrode 130. The third photoresist layer PR3 may be arranged in the second-3 opening OP2-3 and may cover the third sacrificial layer 430. Accordingly, the third sacrificial layer 430 may be sealed by the third photoresist layer PR3. For example, the third sacrificial layer 430 may include Al or Ag.

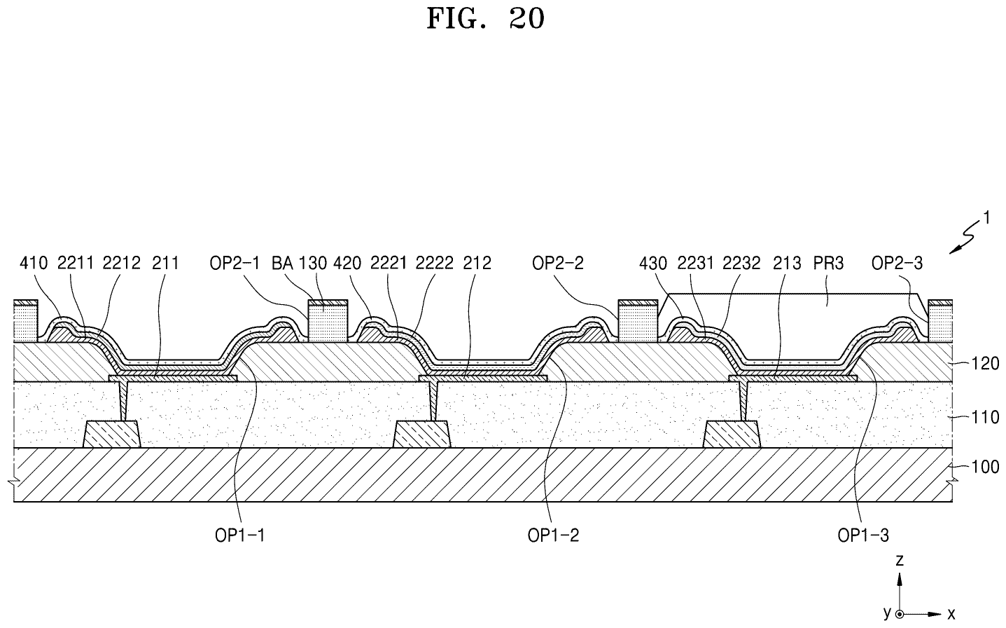

Referring to FIG. 20, the method of manufacturing the display device 1 may include removing the third-1 functional layer 2231 and the third emission layer 2232 that are disposed on the first pixel electrode 211 and the second pixel electrode 212.

The third-1 functional layer 2231 and the third emission layer 2232, which do not overlap the third photoresist layer PR3, may be dry-etched or wet-etched. For example, the third-1 functional layer 2231 and the third emission layer 2232 accommodated in the first-1 opening OP1-1 and the second-1 opening OP2-1 may be removed. The third-1 functional layer 2231 and the third emission layer 2232 accommodated in the first-2 opening OP1-2 and the second-2 opening OP2-2 may be removed. The third-1 functional layer 2231 and the third emission layer 2232 disposed on the heating electrode 130 may be removed. The third-1 functional layer 2231, the third emission layer 2232, and the third sacrificial layer 430, which overlap the third photoresist layer PR3, may not be removed.

In this case, the first-1 functional layer 2211 and the first emission layer 2212 may be covered by the first sacrificial layer 410, and thus, the first-1 functional layer 2211 and the first emission layer 2212 may not be removed. The second-1 functional layer 2221 and the second emission layer 2222 may be covered by the second sacrificial layer 420, and thus, the second-1 functional layer 2221 and the second emission layer 2222 may not be removed.

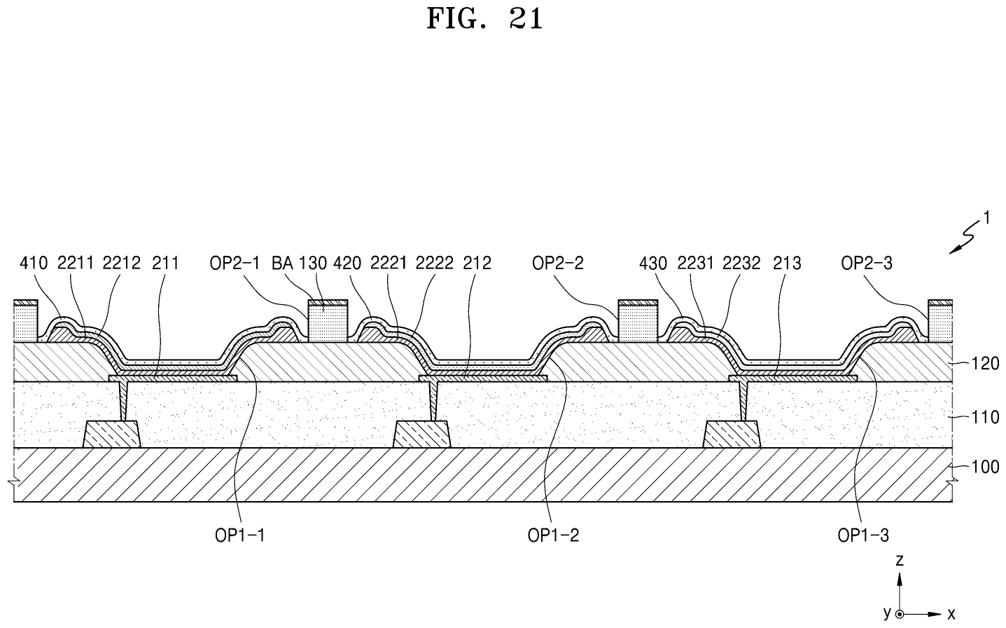

Referring to FIG. 21, the method of manufacturing the display device 1 may include removing the third photoresist layer PR3. Accordingly, the third sacrificial layer 430 may be exposed to the outside.

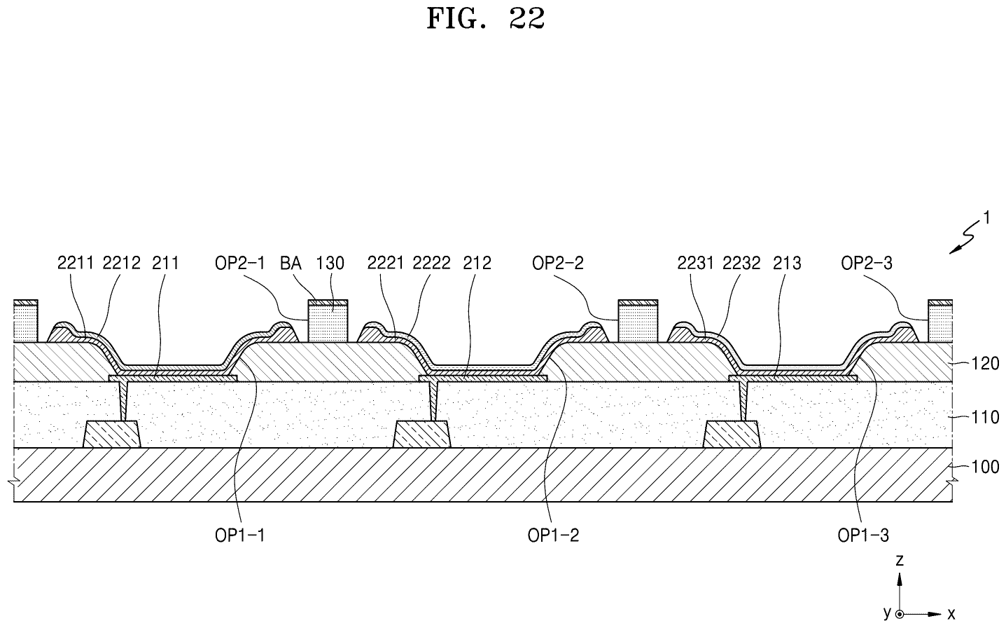

Referring to FIG. 22, the method of manufacturing the display device 1 may include removing the first sacrificial layer 410, the second sacrificial layer 420, and the third sacrificial layer 430. Accordingly, the first emission layer 2212, the second emission layer 2222, and the third emission layer 2232 may be exposed. In case that the first sacrificial layer 410, the second sacrificial layer 420, and the third sacrificial layer 430 are removed, the display device 1 may be baked in a vacuum state. For example, a temperature at which the display device 1 is baked may be about 90 degrees Celsius to about 100 degrees Celsius. Accordingly, moisture remaining in the display device 1 may be removed.

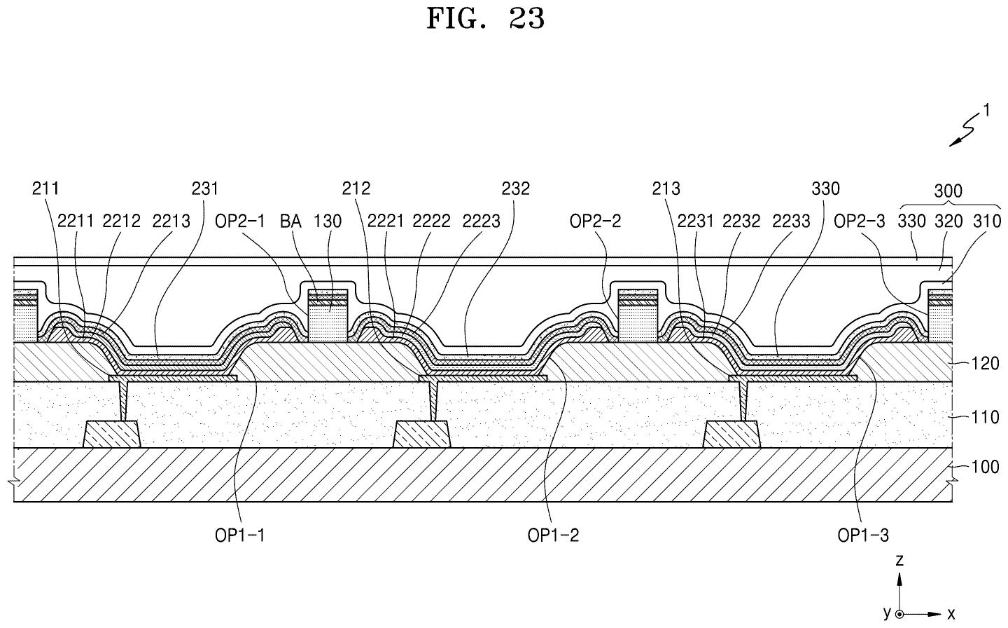

Referring to FIG. 23, the method of manufacturing the display device 1 may include disposing the first-2 functional layer 2213 on the first emission layer 2212, disposing the second-2 functional layer 2223 on the second emission layer 2222, and disposing the third-2 functional layer 2233 on the third emission layer 2232.

Each of the first-2 functional layer 2213, the second-2 functional layer 2223, and the third-2 functional layer 2233 may be in contact with the heating electrode 130. The first-2 functional layer 2213, the second-2 functional layer 2223, and the third-2 functional layer 2233 may include the same material, and the disposing of the first-2 functional layer 2213, the disposing of the second-2 functional layer 2223, and the disposing of the third-2 functional layer 2233 may be simultaneously performed.

The method of manufacturing the display device 1 may include disposing the first common electrode 231 on the first emission layer 2212, disposing the second common electrode 232 on the second emission layer 2222, and disposing the third common electrode 233 on the third emission layer 2232.

The first common electrode 231 may be disposed on the first-2 functional layer 2213, and the second common electrode 232 may be disposed on the second-2 functional layer 2223, and the third common electrode 233 may be disposed on the third-2 functional layer 2233. Each of the first common electrode 231, the second common electrode 232, and the third common electrode 233 may be in contact with the heating electrode 130. The first common electrode 231, the second common electrode 232, and the third common electrode 233 may include the same material, and the disposing of the first common electrode 231, the disposing of the second common electrode 232, and the disposing of the third common electrode 233 may be simultaneously performed.

In this process, on the barrier layer BA, the same material as the first-2 functional layer 2213, the second-2 functional layer 2223, and the third-2 functional layer 2233 may be disposed, and thereon, the same material as the first common electrode 231, the second common electrode 232, and the third common electrode 233 may be disposed.

The method of manufacturing the display device 1 may include disposing the thin-film encapsulation layer 300. The thin-film encapsulation layer 300 may be disposed on the bank layer 120 and may be in contact with the first common electrode 231, the second common electrode 232, the third common electrode 233, the heating electrode 130, and the barrier layer BA. The disposing of the thin-film encapsulation layer 300 may include disposing the first inorganic encapsulation layer 310, disposing the organic encapsulation layer 320 on the first inorganic encapsulation layer 310, and disposing the second inorganic encapsulation layer 330 on the organic encapsulation layer 320.

According to one or more embodiments, durability of a display device may be improved, and a method of manufacturing a display device may be simplified.

Effects of one or more embodiments are not limited to the effects described above, and other effects not described could be clearly understood by a person skilled in the art from the description of the claims.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a circuit element layer disposed on a substrate and comprising a pixel circuit;
a first pixel electrode disposed on the circuit element layer;
a bank layer disposed on the circuit element layer and comprising a first-1 opening that exposes a part of the first pixel electrode;
a heating electrode disposed on the bank layer and comprising a second-1 opening that overlaps the first-1 opening;
a first emission layer disposed on the first pixel electrode, accommodated in the first-1 opening, and spaced apart from the heating electrode; and
a first common electrode disposed on the first emission layer, accommodated in the second-1 opening, and contacting the heating electrode.

2. The display device of claim 1, wherein an end of the first emission layer is convex.

3. The display device of claim 1, wherein the first common electrode covers the first emission layer.

4. The display device of claim 1, further comprising:
a barrier layer having an insulating material and disposed on the heating electrode.

5. The display device of claim 1, further comprising:
a first-1 functional layer disposed between the first pixel electrode and the first emission layer and spaced apart from the heating electrode.

6. The display device of claim 1, further comprising:
a first-2 functional layer disposed between the first emission layer and the first common electrode and contacting the heating electrode.

7. The display device of claim 1, further comprising:
a second pixel electrode disposed on the circuit element layer and spaced apart from the first pixel electrode;
a second emission layer disposed on the second pixel electrode and spaced apart from the heating electrode; and
a second common electrode disposed on the second emission layer and contacting the heating electrode.

8. The display device of claim 7, wherein the first emission layer and the second emission layer emit light of different colors.

9. The display device of claim 7, wherein the first common electrode and the second common electrode are spaced apart from each other.

10. A method of manufacturing a display device, the method comprising:
disposing a circuit element layer on a substrate;
disposing a first pixel electrode, a second pixel electrode, and a third pixel electrode on the circuit element layer;
disposing a bank layer on the circuit element layer, the bank layer comprising a first-1 opening that exposes a part of the first pixel electrode, a first-2 opening that exposes a part of the second pixel electrode, and a first-3 opening that exposes a part of the third pixel electrode;
disposing a heating electrode on the bank layer;
disposing a first emission layer on the first pixel electrode, the second pixel electrode, and the third pixel electrode; and
performing a first Joule heating on the heating electrode.

11. The method of claim 10, wherein, in the disposing of the first emission layer, the first emission layer contacts the heating electrode.

12. The method of claim 10, wherein, in the performing of the first Joule heating on the heating electrode, the first emission layer is spaced apart from the heating electrode.

13. The method of claim 10, wherein, in the performing of the first Joule heating on the heating electrode, an end of the first emission layer is convex.

14. The method of claim 10, further comprising:
disposing a first sacrificial layer on the first emission layer arranged in the first-1 opening;
disposing a first photoresist layer on the first sacrificial layer;
removing the first emission layer disposed on the second pixel electrode and the third pixel electrode; and
removing the first photoresist layer.

15. The method of claim 14, further comprising:
disposing a second emission layer on the first sacrificial layer, the second pixel electrode, and the third pixel electrode;
performing a second Joule heating on the heating electrode;
disposing a second sacrificial layer on the second emission layer arranged in the first-2 opening;
disposing a second photoresist layer on the second sacrificial layer;
removing the second emission layer disposed on the first pixel electrode and the third pixel electrode; and
removing the second photoresist layer.

16. The method of claim 15, wherein the first emission layer and the second emission layer emit light of different colors.

17. The method of claim 15, further comprising:
disposing a third emission layer on the first sacrificial layer, the second sacrificial layer, and the third pixel electrode;
performing a third Joule heating on the heating electrode;
disposing a third sacrificial layer on the third emission layer arranged in the first-3 opening;
disposing a third photoresist layer on the third sacrificial layer;
removing the third emission layer disposed on the first pixel electrode and the second pixel electrode; and
removing the third photoresist layer.

18. The method of claim 17, further comprising:
removing the first sacrificial layer, the second sacrificial layer, and the third sacrificial layer.

19. The method of claim 17, further comprising:
disposing a first common electrode on the first emission layer to contact the heating electrode;
disposing a second common electrode on the second emission layer to contact the heating electrode; and
disposing a third common electrode on the third emission layer to contact the heating electrode.

20. The method of claim 19, wherein the disposing of the first common electrode, the disposing of the second common electrode, and the disposing of the third common electrode are simultaneously performed.
